(19) United States
(12) Patent Application Publication
(10) Pub. No.: US 2026/0271727 A1
(43) Pub. Date: Sep. 10, 2026

(54) LARGE AREA INTERPOSERS, SYSTEMS COMPRISING THE SAME, AND METHODS FOR PRODUCING THE SAME

(71) Applicant: Taiwan Semiconductor Manufacturing Company, Ltd., Hsinchu (TW)

(72) Inventors: Tzu Jung Tien, Hsinchu County (TW); Li-Hsin Chu, New Taipei City (TW); Jia-Ren Chen, Tainan City (TW)

(73) Assignee: Taiwan Semiconductor Manufacturing Company, Ltd., Hsinchu (TW)

(21) Appl. No.: 19/073,485

(22) Filed: Mar. 7, 2025

(51) Int. Cl. H10W 42/00; H10W 70/05; H10W 70/60; H10W 90/00

(52) U.S. Cl. CPC H10W 42/00; H10W 70/095; H10W 70/611; H10W 90/00; H10W 90/401

(57) ABSTRACT

Systems that include large area interposers and method for producing the interposers are provided. The interposers include an interconnection area that includes frontside metal layers, backside metal layers, and through silicon vias connecting the frontside metal layers and the backside metal layers in the interconnection area, a keep-out-zone area that surrounds a perimeter of the interconnection area, and a first seal ring area that surrounds a perimeter of the keep-out-zone area. The first seal ring area includes a first seal ring interconnect structure. The interconnection area is larger than a shot size of a lithography system used for production thereof. The interconnection area is segmented into two or more sub-regions that are each equal to or smaller than the shot size of the lithography system.

### BACKGROUND

The semiconductor integrated circuit (IC) industry has continued its rapid growth in recent years. Technological advancements in IC materials and design have led to continuous improvements in the generations of ICs. With each new generation, the circuits become smaller and more complex than their predecessors, resulting in higher functional density (i.e., the number of interconnected devices per chip area) and smaller geometric sizes (i.e., the smallest component or line that can be created using a fabrication process). This scaling down process has been beneficial in increasing production efficiency and reducing associated costs. However, as feature sizes continue to shrink, the manufacturing process becomes more challenging, and it becomes increasingly difficult to ensure the reliability of semiconductor devices. As a result, the industry faces the ongoing challenge of developing processes that can create smaller, more reliable ICs.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 schematically represents a cross-sectional view of a portion of a semiconductor system that includes a first large area interposer in accordance with some embodiments;

FIG. 2 is a flowchart illustrating an exemplary method for forming certain layers of an interposer, such as the large area interposer of FIG. 1, in accordance with some embodiments;

FIGS. 3 and 4 schematically represent perspective and top views of a second large area interposer formed in a wafer in accordance with some embodiments;

FIGS. 5 and 6 schematically represent top and cross-sectional views of a third large area interposer in accordance with some embodiments;

FIGS. 7 and 8 schematically represent top and cross-sectional views of a fourth large area interposer in accordance with some embodiments;

FIGS. 9 and 10 schematically represent top and cross-sectional views of a fifth large area interposer in accordance with some embodiments;

FIGS. 11 and 12 schematically represent top and cross-sectional views of a sixth large area interposer in accordance with some embodiments;

FIG. 13 schematically represents a top view of a seventh large area interposer having a first seal ring area with corners having diagonal edges in accordance with some embodiments;

FIGS. 14 and 15 schematically represent top and cross-sectional views of an eighth large area interposer in accordance with some embodiments;

FIGS. 16 and 17 schematically represent top and cross-sectional views of a ninth large area interposer in accordance with some embodiments;

FIGS. 18 and 19 schematically represent top and cross-sectional views of a tenth large area interposer in accordance with some embodiments;

FIG. 20 schematically represents a top view of a eleventh large area interposer having a second seal ring area with corners having diagonal edges in accordance with some embodiments;

FIG. 21 schematically represents a top view of a twelfth large area interposer having first and second seal ring areas with corners having diagonal edges in accordance with some embodiments; and

FIG. 22 is a flowchart illustrating an exemplary method for forming a large area interposer in accordance with some embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, the terms such as "first," "second" and "third" describe various elements, components, regions, layers and/or sections, but these elements, components, regions, layers and/or sections should not be limited by these terms. These terms may be only used to distinguish one element, component, region, layer or section from another. The terms such as "first," "second" and "third" when used herein do not imply a sequence or order unless clearly indicated by the context.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element’s or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

Some embodiments of the disclosure will now be described with reference to the drawings, wherein like reference numerals are generally used to refer to like elements throughout. In the following description, for purposes of explanation, numerous specific details are set forth in order to provide a thorough understanding of the claimed subject matter. It is evident, however, that the claimed subject matter may be practiced without these specific details. In other instances, structures and devices are illustrated in block diagram form in order to facilitate describing the claimed subject matter.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

An interposer is a specialized layer or substrate that is used to connect multiple components or integrated circuits (ICs) within a system. The interposer is typically disposed between the ICs and a main printed circuit board (PCB) to facilitate interconnections therebetween. Interposers are particularly useful in advanced packaging techniques, such as three-dimensional (3D) ICs or systems-in-package (SiP), where multiple ICs or dies are stacked or placed close together.

A plurality of interposers can be formed on a single wafer. The interposers can be formed, for example, by at least one of deposition processes, photolithography processes, etching processes, chemical-mechanical polish (CMP) processes, implantation processes, annealing processes, cleaning processes, other known semiconductor processes, or any combinations thereof. Once the plurality of interposers have been produced, the wafer may be segmented to separate each of the interposers. Typically, each of the interposers are surrounded by, for example, a keep-out zone and one or more seal rings. Further, a scribe line may be provided between each of the interposers. These keep-out zones, seal rings, and scribe lines are intended to protect the interposers during the segmentation process.

In general, the size of each of the interposers has been limited based on the capabilities of the semiconductor processing equipment. For example, interposers may be produced, in part, using lithography processes that include forming a mask layer over a layer to be modified. In some embodiments, the mask layer may include multiple layers such as, for example, a pad oxide layer (e.g., silicon oxide) and an overlying pad nitride layer (e.g., silicon nitride, silicon oxynitride, silicon carbonitride, etc.), wherein the nitride layer is a photoresist material. The processes may then include patterning the mask layer using photolithography techniques that irradiate (expose) and develop the mask layer to remove a portion thereof and thereby define a patterned mask. Once the patterned mask is formed, an etching process may be used to etch exposed portions of the layer to be modified while the patterned mask protect the underlying materials.

The photolithography systems used for producing the interposers as described above may have a limited shot size (e.g., exposure field size or field of view (FoV)) for irradiating (exposing) the mask layer. Existing processes for producing interposers may require the shot size to at least cover the full size of the desired interposer. However, as processing demands increase, it may be desirable to produce larger size interposers.

Presented herein are embodiments of semiconductor structures and of methods for forming semiconductor structures with large surface areas, for example, in excess of a shot size of a lithography system used to produce the semiconductor structures. For convenience, the semiconductor structures and methods will be described herein in reference to production of interposers. However, the semiconductor structures and methods are not limited to this application. For example, the semiconductor structures and methods may include ICs having hybrid bonds therebetween.

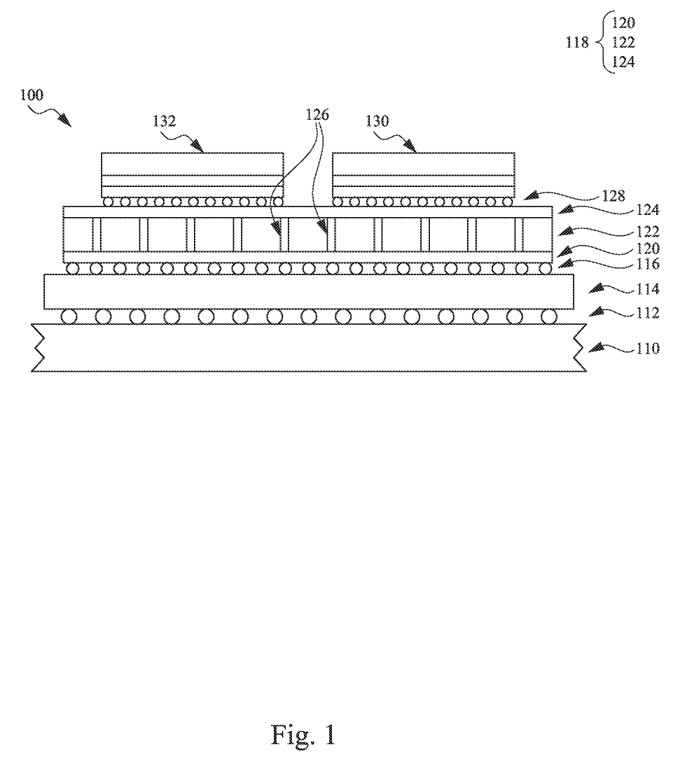

FIG. 1 is a cross-sectional view of a portion of an example semiconductor system 100 in accordance with an embodiment. In some examples, the semiconductor system 100 may include a system in package (SiP). A SiP is an advanced packaging technology that integrates multiple functional components, such as microprocessors, memory, sensors, power management units, etc., into a single package. In this example, the semiconductor system 100 includes a printed circuit board (PCB) 110, a substrate 114, an interposer 118, and a pair of dies 130, 132.

The dies 130, 132 (e.g., chips or integrated circuits (ICs)) may each be any of various functional components such as, but not limited to, processors, memory modules (e.g., DRAM, flash memory), power management ICs, sensors, or application-specific integrated circuits (ASICs). Each of the dies 130, 132 may perform a specific task, such as computing, storage, or sensing.

The dies 130, 132 are electrically connected by the interposer 118. The interposer 118 is a device configured to route electrical signals and power between the dies 130, 132. In this example, the interposer 118 includes one or more backside metal layers 120, an interposer substrate 122, one or more frontside or topside metal layers 124, and a plurality of through-silicon vias (TSVs) 126 extending through the interposer substrate 122 connecting the topside metal layer(s) 124 and the backside metal layer(s) 120. The topside metal layer(s) 124 may include a plurality of interconnect structures (not shown) electrically connected to corresponding interconnect structures (not shown) of the dies 130, 132 with, for example, micro-bumps 128.

The backside metal layer(s) 120 may be connected to the substrate 114 with, for example, flip-chip bumps 116. The dies 130, 132, the interposer 118, and the substrate 114 may define or be components of a package that may be connected to the PCB 110 with, for example, package bumps 112. The substrate 114 may also provide mechanical stability. Although not shown, the substrate 114 may include, for example, various metal layers and TSVs configured to electrically connect the interposer 118, and therefore the dies 130, 132, to the PCB 110. Similarly, the PCB 110 may include various metal layers, traces, pads, etc. configured to send and receive electrical signals between the dies 130, 132 and other components connected to the PCB 110.

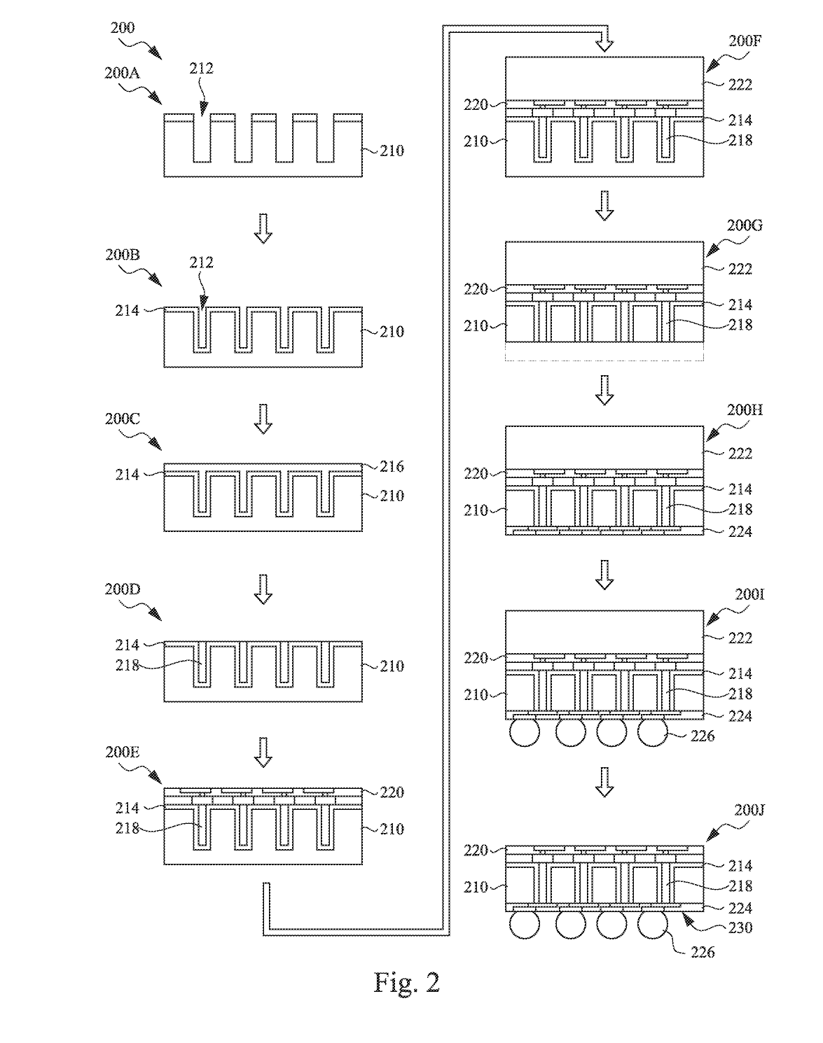

Referring to FIG. 2, an exemplary method 200 is presented for forming an interposer 230 and/or portions thereof, such as the interposer 118 of FIG. 1. At step 200A, the method 200 includes providing a substrate 210 (e.g., the interposer substrate 122 of FIG. 1) and forming trenches 212 in a topside thereof, for example, via an etching process. At step 200B, the method 200 includes forming a seed or barrier layer 214 over surfaces of the trenches 212 and a topside surface of the substrate 210. The barrier layer 214 may include, for example, an oxide material and may be formed using various techniques such as certain deposition processes. At step 200C, the method 200 includes forming a conductive layer 216 that fills the trenches 212 and covers the barrier layer 214. The conductive layer 216 may be, for example, a metallic material such as copper or an alloy thereof and may be formed using various techniques such as certain plating processes.

At step 200D, the method 200 includes removing excess material from the conductive layer 216 to form TSVs 218 isolated by the barrier layer 214. The excess material may be removed using various techniques such as certain chemical mechanical polishing (CMP) processes. At 200E, the method 200 includes forming one or more frontside metal layers 220 (e.g., the topside metal layers 124 of FIG. 1) over exposed portions of the TSVs 218 and the barrier layer 214. The frontside metal layers 220 may include dielectric layers having interconnect structures formed therein that are electrically connected with the TSVs 218. The interconnect structures may include a plurality of metal layers and vias. The interconnect structures may be formed of various materials and processes including those known in the art. Nonlimiting examples, of processes for forming the interconnect structures may include one or more of deposition, etching, implantation, photolithography, annealing, and other suitable processes.

At step 200F, the method 200 includes forming a support layer 222 over the frontside metal layers 220. The support layer 222 is configured to provide mechanical support during subsequent processing steps. The support layer 222 may be formed using various techniques such as certain deposition processes. At step 200G, the method 200 includes removing backside portions of the substrate 210 to expose backside portions of the TSVs 218. The backside portions of the substrate 210 may be removed with various techniques such as certain planarization processes.

At step 200H, the method 200 includes forming one or more backside metal layers 224 (e.g., the backside metal layers 120 of FIG. 1) over the exposed backside portions of the TSVs 218. The backside metal layers 224 may include dielectric layers having interconnect structures formed therein that are electrically connected with the TSVs 218. The interconnect structures may include a plurality of metal layers and vias. The interconnect structures may be formed of various materials and processes including those known in the art. Nonlimiting examples, of processes for forming the interconnect structures may include one or more of deposition, etching, implantation, photolithography, annealing, and other suitable processes.

At step 200I, the method 200 includes forming solder bumps 226 (e.g., the flip-chip bumps 116 of FIG. 1) on the backside surfaces of the backside metal layers 224 that are in contact with the interconnect structure thereof. At step 200J, the method 200 includes removing the support layer 222 from the frontside metal layers 220 to result in an interposer 230. The support layer 222 may be removed with various techniques such as certain debonding processes.

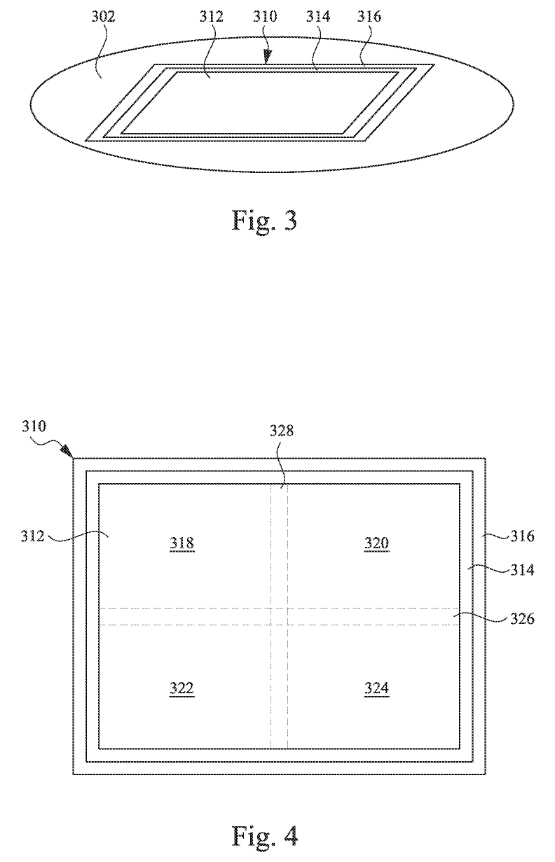

FIGS. 3 and 4 represent perspective and top views, respectively, of a large area interposer 310 that may be produced, for example, by the method 200. In some examples, the large area interposer 310 may be used as the interposer 118 of the semiconductor system 100. The large area interposer 310 may be formed on a wafer 302. The large area interposer 310 includes an interconnection area 312, that is, a region that includes functional components of the large area interposer 310 including, for example, frontside metal layers, backside metal layers, and TSVs. For example, the interconnection area 312 may be formed by the method 200 of FIG. 2. The interconnection area 312 is surrounded by a keep-out-zone area 314 which in turn is surrounded by a seal ring area 316.

The keep-out-zone area 314 is an area of the large area interposer 310 that does not include any critical components (such as vias, traces, or solder bumps). The keep-out-zone area 314 may be configured to reduce a likelihood of interference with other components of the large area interposer 310, protect sensitive areas, promote the proper mechanical and electrical integrity of the large area interposer 310, maintain necessary space for cooling, and/or to allow for alignment and bonding with other components during assembly. In some examples, the keep-out-zone area 314 may include one or more dummy fill structures (e.g., non-functional interconnect structures).

The seal ring area 316 is an area that includes an interconnect structure referred to as a seal ring that is configured to function as a physical barrier along the perimeter of the large area interposer 310. The seal ring interconnect structure may include layers of various materials configured to protect the large area interposer 310 from, for example, contamination and mechanical stress during the manufacturing process, such as the die-sawing process where the wafer 302 is cut to remove the large area interposer 310.

Unlike certain existing methods for producing interposers, the large area interposer 310 may cover a substantial portion of the wafer 302 over an area in excess of a shot size of a lithography system used to produce the large area interposer 310. In the example of FIG. 4, the interconnection area 312 of the large area interposer 310 has an area that is almost four times as large as the shot size of an exemplary lithography system used to produce the interconnection area 312. As examples, certain existing lithography systems have a maximum shot size (exposure field size) of about 22 mm x 22 mm or 26 mm x 33 mm. In some examples, the large area interposer 310 may have an area that is greater than about 22 mm x 22 mm, such as equal to or greater than about 40 mm x 22 mm, such as equal to or greater than about 40 mm x 40 mm.

To overcome the limitations of the lithography system, the interconnection area 312 may be formed with a combination of four sub-regions 318, 320, 322, 324 each formed by separate shots from the lithography system. To ensure complete coverage during production, the four sub-regions 318, 320, 322, 324 may overlap at edges thereof. For example, first and second sub-regions 318, 320 may overlap with third and fourth sub-regions 322, 324 to define a first region of double exposure 326, and first and third sub-regions 318, 322 may overlap with second and fourth sub-regions 320, 324 to define a second region of double exposure 328. Therefore, each of the four sub-regions 318, 320, 322, 324 may have surface areas up to the shot size of the lithography system, and as such the interconnection area 312 may have a total surface area of up to four times the shot size of the lithography system minus the areas of the first and second regions of double exposure 326, 328. Notably, the interconnection area 312 may include more or less of the overlapping sub-regions 318, 320, 322, 324 (e.g., 2, 6, 8, 9, 10, etc.), and the sizes thereof may vary based on, for example, the shot size of the specific lithography system used (or other limiting production system) and/or the desired sizes of the regions of double exposure. The large area interposer 310 includes only one of the keep-out-zone area 314 and only one of the seal ring area 316 each surrounding all of the overlapping sub-regions 318, 320, 322, 324, that is, the large area interposer 310 does not include separate keep-out-zone areas and seal ring areas surrounding each of the overlapping sub-regions 318, 320, 322, 324 with scribe lines therebetween. In this manner, the large area interposer 310 may be produced having large interconnection areas that are not limited by certain manufacturing systems.

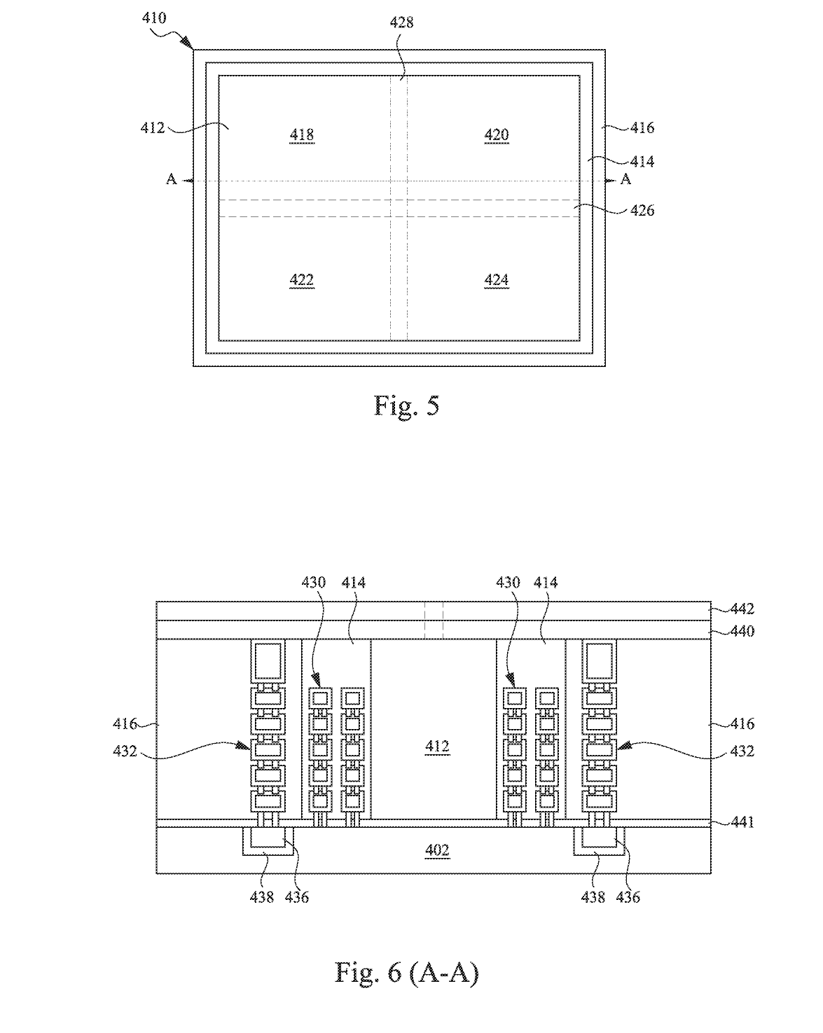

FIGS. 5-21 represent various nonlimiting aspects of large area interposers (e.g., the interposer 118 of FIG. 1, the interposer 230 of FIG. 2, and/or the large area interposer 310 of FIGS. 3 and 4) in accordance with various examples. It should be noted that these examples are merely for illustrative purposes and the large area interposers formed in accordance with methods disclosed herein may have other configurations, including various combinations of the components represented in FIGS. 5-21. For convenience, consistent reference numbers are used throughout FIGS. 5-21 to identify the same or functionally related/equivalent elements, but with a numerical prefix (1, 2, or 3, etc.) added to distinguish the particular example from other examples of the of the figures. In view of similarities between the examples, the following discussion of FIGS. 5-21 will focus primarily on aspects of the examples that differ from the other examples in some notable or significant manner. Other aspects of the examples not discussed in any detail can be, in terms of structure, function, materials, etc., essentially as was described for one or more of the other examples, including the example of FIGS. 1-4. It should be understood that the various regions and components of the large area interposers are represented for ease of the following description and are not to scale.

FIGS. 5 and 6 represent top and cross-sectional (along line A-A) views, respectively, illustrating aspects of an interposer 410 that includes an interconnection area 412 having overlapping sub-regions 418, 420, 422, 424 with regions of double exposure 426, 428, a keep-out-zone area 414, and a seal ring area 416. The interconnection area 412 may include various components (e.g., traces, vias, etc.) that are not shown for clarity. At this stage in the production process, the interposer 410 includes a mask layer for use during a photolithography process. The mask layer includes a pad oxide layer 440 (e.g., silicon oxide) and an overlying pad nitride layer 442 (e.g., silicon nitride, silicon oxynitride, silicon carbonitride, etc.), wherein the nitride layer is a photoresist material.

One or more keep-out-zone interconnect structures 430 may be formed in the keep-out-zone area 414 and one or more seal ring interconnect structures 432 may be formed in the seal ring area 416 that are each configured to function as a protective barrier about the interconnection area 412. The keep-out-zone interconnect structures 430 and the seal ring interconnect structures 432 may include a plurality of metal layers and vias. The keep-out-zone interconnect structures 430 and the seal ring interconnect structures 432 may be formed of various materials and processes including those known in the art. Nonlimiting examples, of processes for forming the keep-out-zone interconnect structures 430 and the seal ring interconnect structures 432 may include one or more of deposition, etching, implantation, photolithography, annealing, and other suitable processes. In this example, the large area interposer 310 includes two keep-out-zone interconnect structures 430 and one seal ring interconnect structure 432.

In some examples, one or more of the keep-out-zone interconnect structure(s) 430 and/or the seal ring interconnect structure(s) 432 may be electrically coupled with one or more semiconductor devices formed in the wafer 402, such as certain transistors (e.g., CMOS, BJT, FET, etc.). The semiconductor devices are configured to modify a conductivity of the keep-out-zone interconnect structures and/or the seal ring interconnect structures coupled thereto. In the example of FIG. 6, the seal ring interconnect structure 432 is coupled with one or more complementary metal-oxide semiconductor (CMOS) devices having an n-well 438 with p-type diffusion regions 436 therein. The CMOS devices are formed in the substrate 402. A polysilicon layer 441 may be formed between the CMOS devices and the overlying layers of the interposer 410.

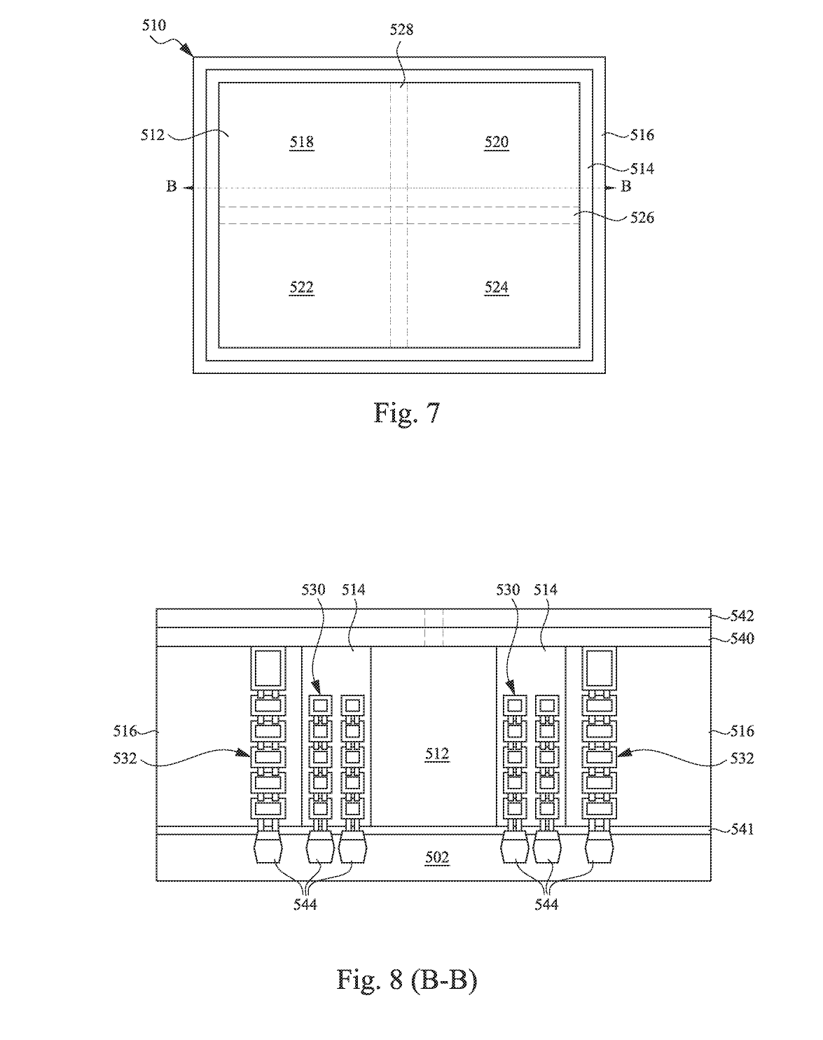

FIGS. 7 and 8 represent top and cross-sectional (along line B-B) views, respectively, illustrating aspects of an interposer 510 that includes an interconnection area 512 having overlapping sub-regions 518, 520, 522, 524 with regions of double exposure 526, 528, a keep-out-zone area 514, and a seal ring area 516. The keep-out-zone area 514 includes keep-out-zone interconnect structures 530 and the first seal ring area 516 includes a first seal ring interconnect structure 532. At this stage in the production process, the interposer 510 includes a mask layer having a pad oxide layer 540 and an overlying pad nitride layer 542. In this example, the keep-out-zone interconnect structures 530 and the seal ring interconnect structure 532 are each electrically coupled with one or more silicon–germanium (SiGe) transistors 544 formed in the substrate 502. A polysilicon layer 541 may be formed between the SiGe transistors 544 and the overlying layers of the interposer 510.

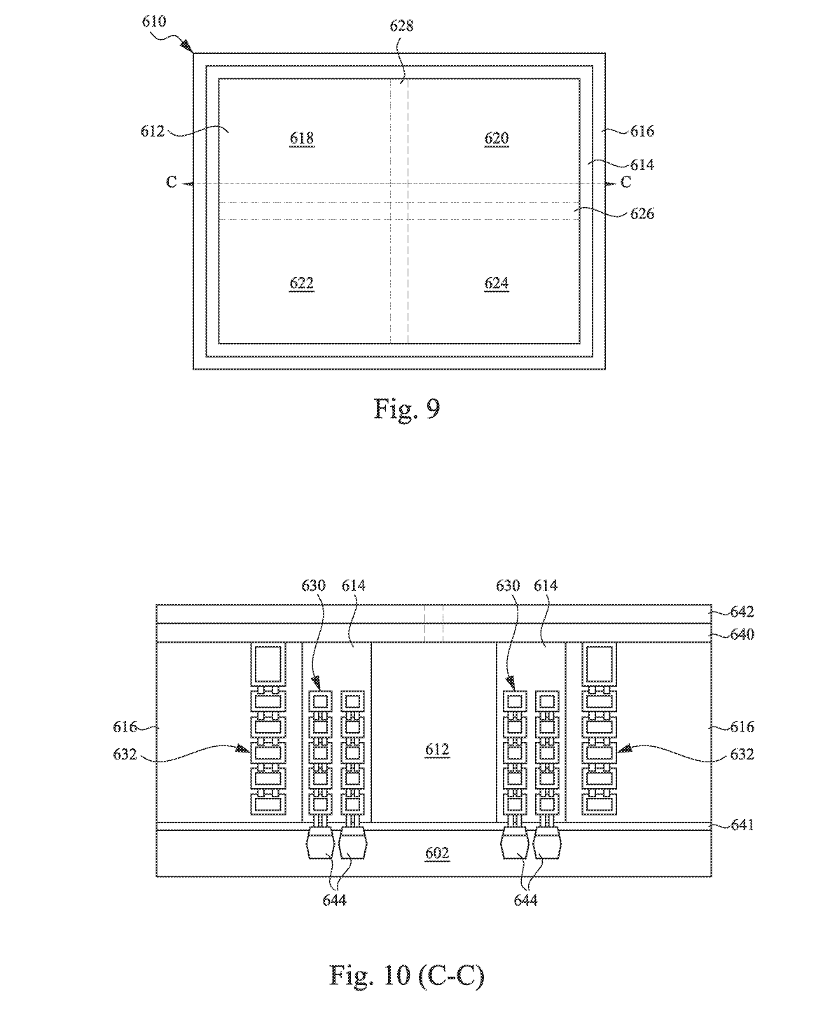

FIGS. 9 and 10 represent top and cross-sectional (along line C-C) views, respectively, illustrating aspects of an interposer 610 that includes an interconnection area 612 having overlapping sub-regions 618, 620, 622, 624 with regions of double exposure 626, 628, a keep-out-zone area 614, and a seal ring area 616. The keep-out-zone area 614 includes keep-out-zone interconnect structures 630 and the first seal ring area 616 includes a first seal ring interconnect structure 632. At this stage in the production process, the interposer 610 includes a mask layer having a pad oxide layer 640 and an overlying pad nitride layer 642. In this example, the keep-out-zone interconnect structures 630 are each electrically coupled with one or more silicon–germanium (SiGe) transistors 644 formed in the substrate 602 whereas the seal ring interconnect structure 632 is not connected to semiconductor devices. A polysilicon layer 641 may be formed between the SiGe transistors 644 and the overlying layers of the interposer 610.

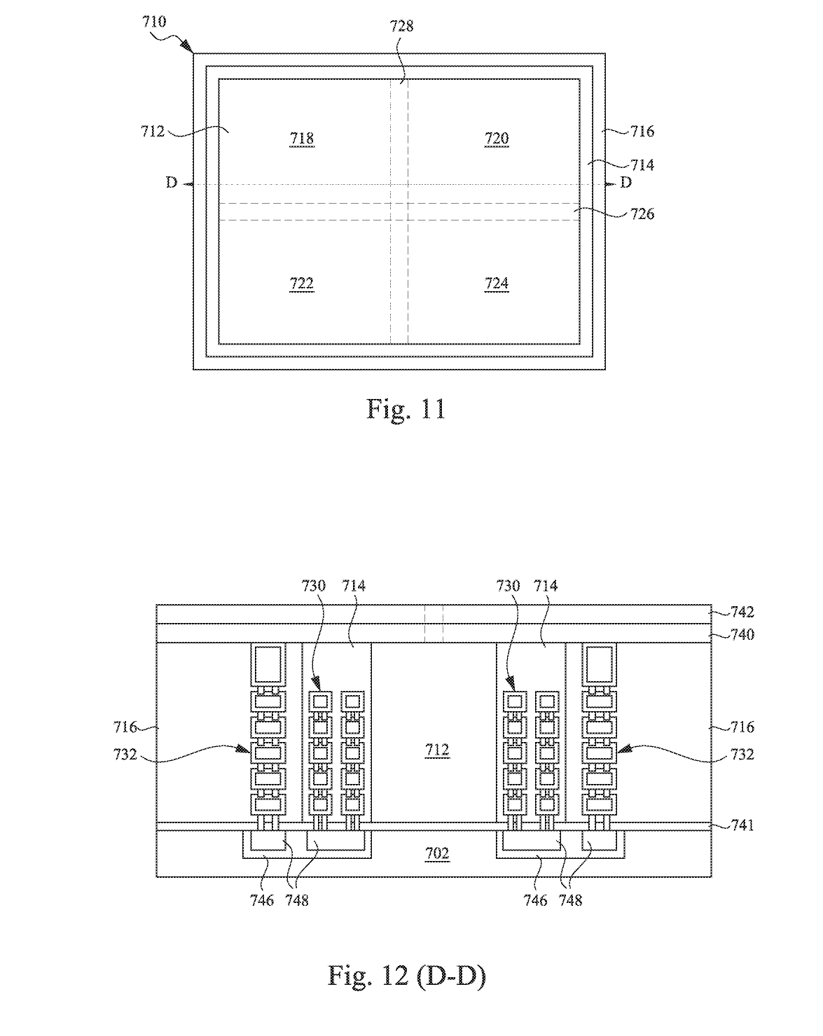

FIGS. 11 and 12 represent top and cross-sectional (along line D-D) views, respectively, illustrating aspects of an interposer 710 that includes an interconnection area 712 having overlapping sub-regions 718, 720, 722, 724 with regions of double exposure 726, 728, a keep-out-zone area 714, and a seal ring area 716. The keep-out-zone area 714 includes keep-out-zone interconnect structures 730 and the first seal ring area 716 includes a first seal ring interconnect structure 732. At this stage in the production process, the interposer 710 includes a mask layer having a pad oxide layer 740 and an overlying pad nitride layer 742. In this example, the keep-out-zone interconnect structures 730 and the seal ring interconnect structure 732 are electrically coupled with one or more CMOS devices having an p-well 746 with n-type diffusion regions 748 therein. The CMOS devices are formed in the substrate 702. A polysilicon layer 741 may be formed between the CMOS devices and the overlying layers of the interposer 710.

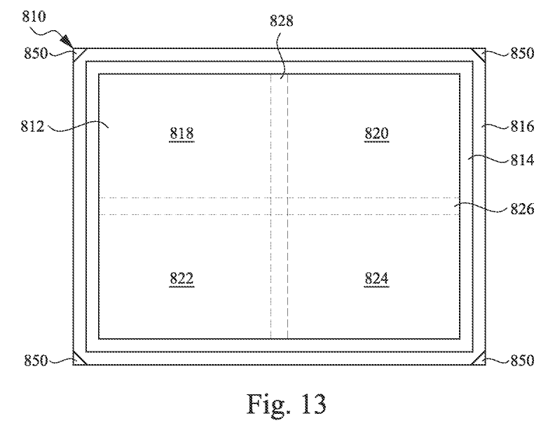

FIG. 13 represents a top view illustrating aspects of an interposer 810 that includes an interconnection area 812 having overlapping sub-regions 818, 820, 822, 824 with regions of double exposure 826, 828, a keep-out-zone area 814, and a seal ring area 816. In some examples, the interposer 810 may include one or more crack mitigation features at corners thereof configured to reduce a likelihood of cracks propagating through the interposer 810. For example, in FIG. 13, corners 850 of the seal ring area 816 have diagonal edges (rather than ninety degree corners). The diagonal corners 850 are configured to reduce propagation of cracks from the corners 850 into more central regions of the interposer 810. Notably, the diagonal corners 850 and/or other crack mitigation features may be included into any of the previously discussed interposers 118, 230, 310, 410, 510, 610, 710 of FIGS. 1-12.

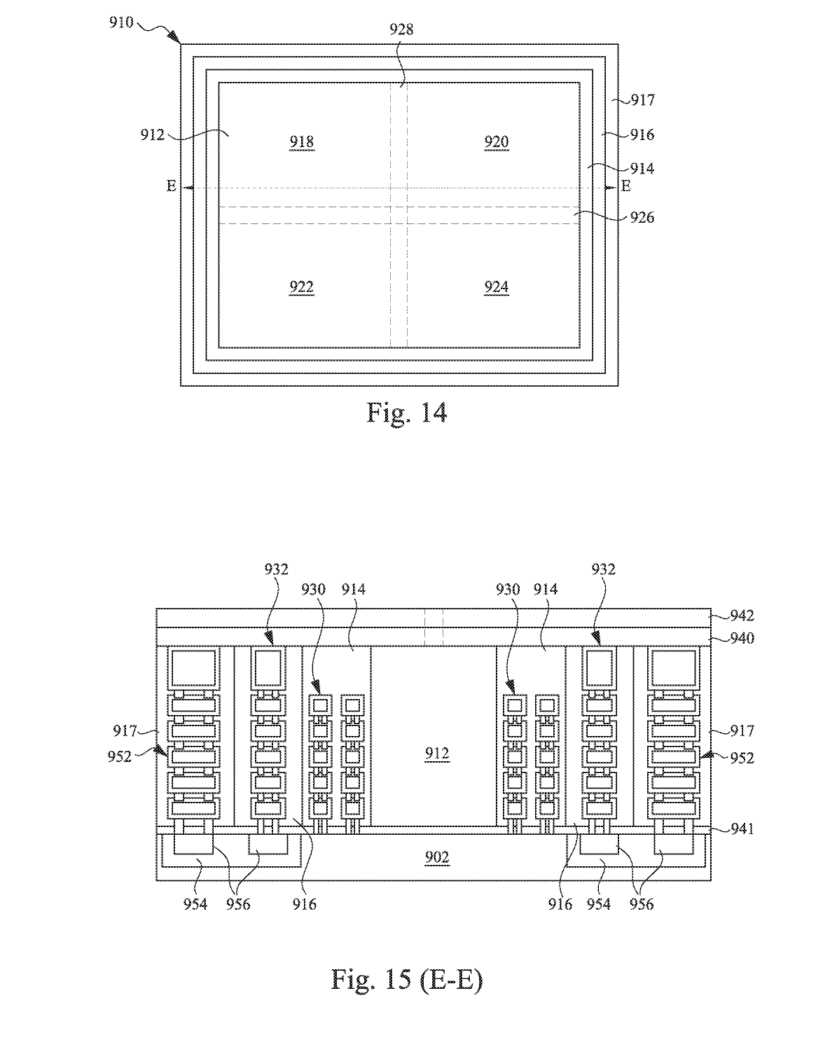

FIGS. 14 and 15 represent top and cross-sectional (along line E-E) views, respectively, illustrating aspects of an interposer 910 that includes an interconnection area 912 having overlapping sub-regions 918, 920, 922, 924 with regions of double exposure 926, 928, a keep-out-zone area 914, a first seal ring area 916, and a second seal ring area 917. The keep-out-zone area 914 includes keep-out-zone interconnect structures 930. At this stage in the production process, the interposer 910 includes a mask layer having a pad oxide layer 940 and an overlying pad nitride layer 942. In this example, the interposer 910 includes a first seal ring interconnect structure 932 (e.g., inner seal ring) in the first seal ring area 916 and a second seal ring interconnect structure 952 (e.g., outer seal ring) in the second seal ring area 917 for protection of the interconnection area 912. The first seal ring interconnect structure 932 and the second seal ring interconnect structure 952 are each coupled with one or more CMOS devices having an n-well 954 with p-type diffusion regions 956 therein. The CMOS devices are formed in the substrate 902. A polysilicon layer 941 may be formed between the CMOS devices and the overlying layers of the interposer 910.

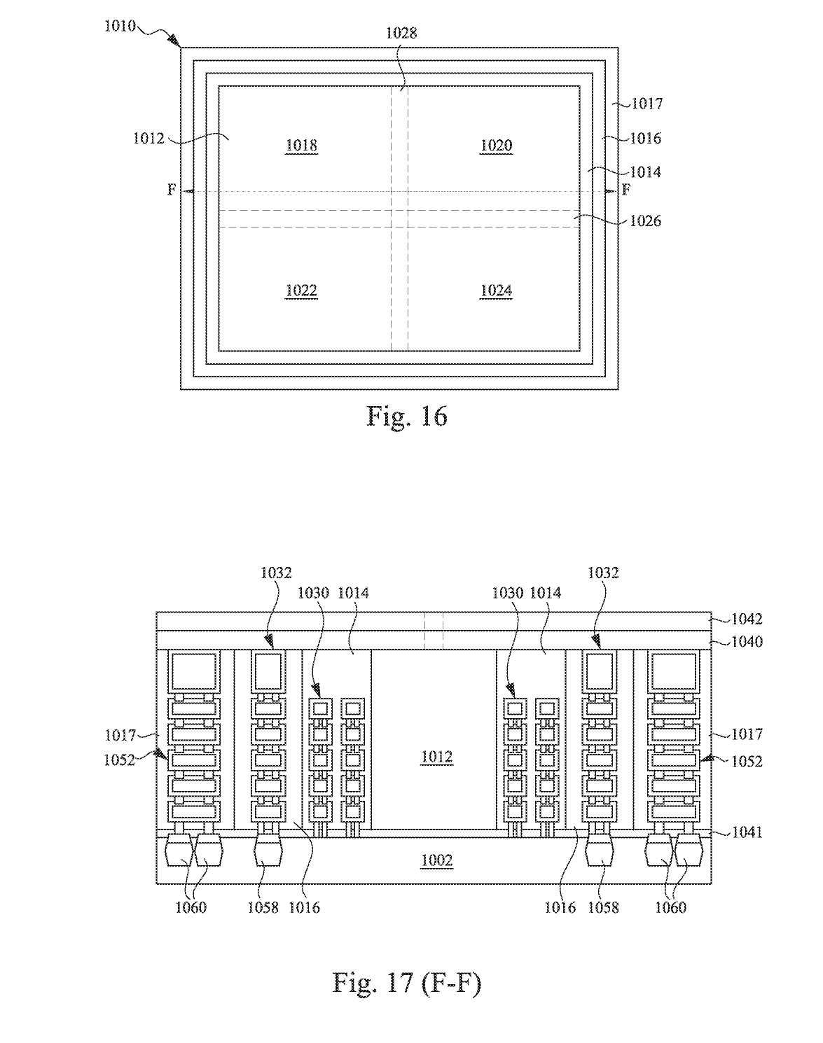

FIGS. 16 and 17 represent top and cross-sectional (along line F-F) views, respectively, illustrating aspects of an interposer 1010 that includes an interconnection area 1012 having overlapping sub-regions 1018, 1020, 1022, 1024 with regions of double exposure 1026, 1028, a keep-out-zone area 1014, a first seal ring area 1016, and a second seal ring area 1052. The keep-out-zone area 1014 includes keep-out-zone interconnect structures 1030, the first seal ring area 1016 includes a first seal ring interconnect structure 1032, and the second seal ring area 1017 includes a second seal ring interconnect structure 1052. At this stage in the production process, the interposer 1010 includes a mask layer having a pad oxide layer 1040 and an overlying pad nitride layer 1042. In this example, the first seal ring interconnect structure 1032 and the second seal ring interconnect structure 1052 are each coupled with one or more silicon–germanium (SiGe) transistors 1058, 1060 formed in the substrate 1002. A polysilicon layer 1041 may be formed between the SiGe transistors 1058, 1060 and the overlying layers of the interposer 1010.

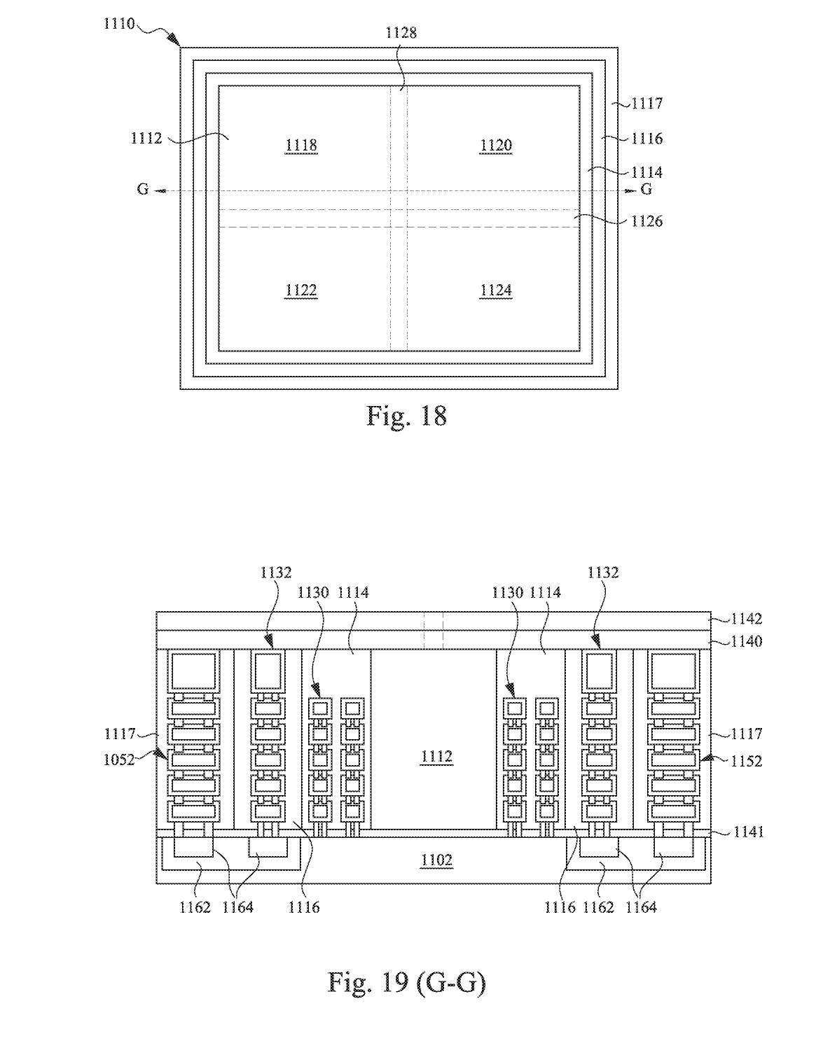

FIGS. 18 and 19 represent top and cross-sectional (along line G-G) views, respectively, illustrating aspects of an interposer 1110 that includes an interconnection area 1112 having overlapping sub-regions 1118, 1120, 1122, 1124 with regions of double exposure 1126, 1128, a keep-out-zone area 1114, a first seal ring area 1116, and a second seal ring area 1117. The keep-out-zone area 1114 includes keep-out-zone interconnect structures 1130, the first seal ring area 1116 includes a first seal ring interconnect structure 1132, and the second seal ring area 1117 includes a second seal ring interconnect structure 1152. At this stage in the production process, the interposer 1110 includes a mask layer having a pad oxide layer 1140 and an overlying pad nitride layer 1142. In this example, the first seal ring interconnect structure 1132 and the second seal ring interconnect structure 1152 are each coupled with one or more CMOS devices having an p-well 1162 with n-type diffusion regions 1164 therein. The CMOS devices are formed in a substrate 1102. A polysilicon layer 1141 may be formed between the CMOS devices and the overlying layers of the interposer 1110.

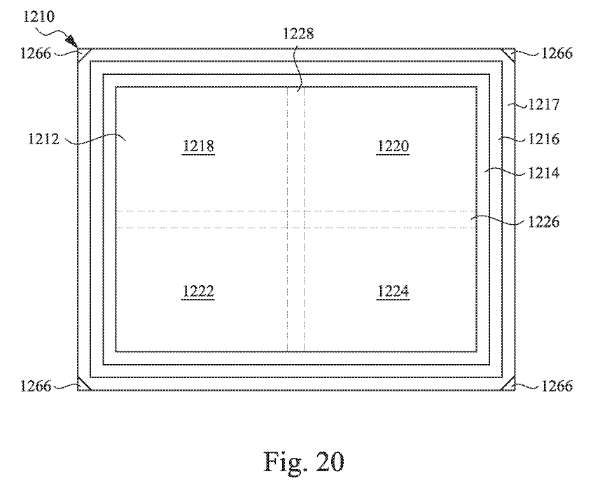

FIG. 20 represents a top view illustrating aspects of an interposer 1210 that includes an interconnection area 1212 having overlapping sub-regions 1218, 1220, 1222, 1224 with regions of double exposure 1226, 1228, a keep-out-zone area 1214, a first seal ring area 1216, and a second seal ring area 1217. In this example, second corners 1266 of the second seal ring area 1217 have one or more crack mitigation features such as diagonal edges (rather than ninety degree corners) that are configured to reduce propagation of cracks from the corners 1266 into more central regions of the interposer 1210. Notably, the diagonal corners and/or other crack mitigation features may be included into any of the previously discussed first seal ring areas 916, 1016, 1116 and/or second seal ring areas 917, 1017, 1117 of the interposers 910, 1010, 1110 of FIGS. 14-19.

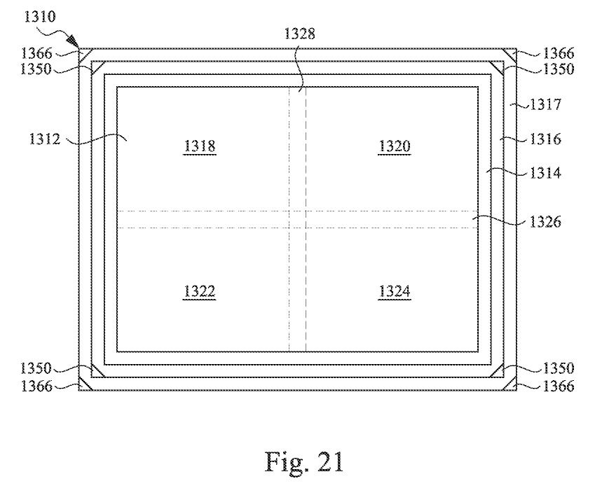

FIG. 21 represents a top view illustrating aspects of an interposer 1310 that includes an interconnection area 1312 having overlapping sub-regions 1318, 1320, 1322, 1324 with regions of double exposure 1326, 1328, a keep-out-zone area 1314, a first seal ring area 1316, and a second seal ring area 1317. In this example, first corners 1350 of the first seal ring area 1316 and second corners 1366 of the second seal ring area 1317 have the diagonal edges and optionally may include one or more other crack mitigation features. Notably, the diagonal corners and/or other crack mitigation features may be included into any of the previously discussed interposers 910, 1010, 1110 of FIGS. 14-19.

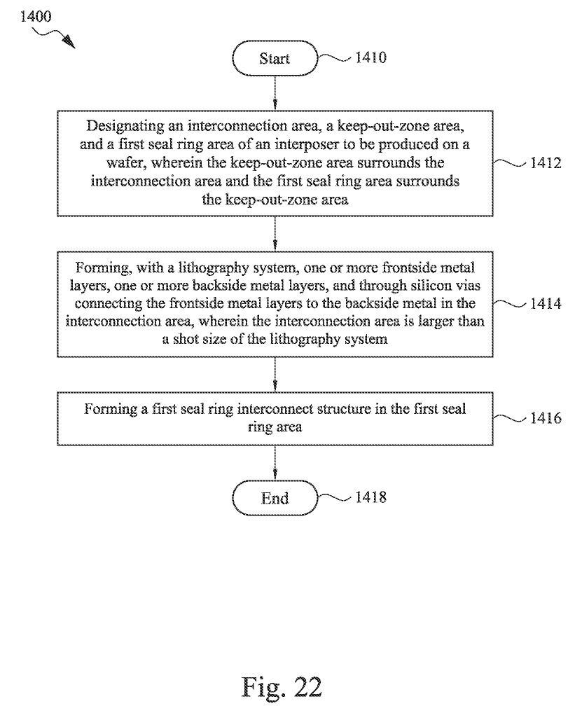

The systems and methods disclosed herein, including the semiconductor system 100 and the interposers 118, 230, 310, 410, 510, 610, 710, 810, 910, 1010, 1110, 1210, 1310, provide for methods of producing large area interposers. For example, FIG. 22 is a flowchart illustrating an exemplary method 1400 for producing a large area interposer. As can be appreciated in light of the disclosure, the order of operation within the method 1400 is not limited to the sequential execution as illustrated in FIG. 22, but may be performed in one or more varying orders as applicable and in accordance with the present disclosure. The method 1400 may start at 1410.

At 1412, the method 1400 may include designating an interconnection area, a keep-out-zone area, and a first seal ring area of an interposer to be produced on a wafer, wherein the keep-out-zone area surrounds the interconnection area and the first seal ring area surrounds the keep-out-zone area. At 1414, the method 1400 may include forming, with a lithography system, one or more frontside metal layers, one or more backside metal layers, and through silicon vias connecting the frontside metal layers to the backside metal layers in the interconnection area. Notably, the interconnection area is larger than a shot size of the lithography system. Therefore, the frontside metal layer(s), backside metal layer(s), and through silicon via(s) may be formed by exposing sub-regions of the interconnection area separately, wherein the sub-regions each have areas that are equal to or less than the hot size of the lithography system. For example, the lithography system may be used to pattern a photoresist layer on the interconnection layer by first exposing a first sub-region thereof and then exposing a second sub-region thereof, wherein the first and second sub-regions overlap, that is, at least some of the first and second regions are exposed by the photolithography system more than once (e.g., exposed with adjacent, overlapping shots). This process may be repeated for multiple sub-regions, and may be performed multiple times during fabrication of the interposer as the various layers are formed to produce the frontside metal layer(s), backside metal layer(s), and through silicon via(s). For example, a mask layer may be patterned with overlapping shots from the lithography system, once the mask layer is fully patterned and developed an etching system may be used to etch the exposed material, and deposition systems may be used to deposit materials to form layers. This series of steps may be repeated a plurality of times to fabricate the interposer. At 1416, the method 1400 may include forming a first seal ring interconnect structure in the first seal ring area.

Optionally, the method 1400 may include designating a second seal ring area that surrounds the first seal ring area, and forming a second seal ring interconnect structure in the second seal ring area. Optionally, the method 1400 may include forming one or more semiconductor devices that are functionally coupled with one or more keep-out-zone interconnect structures, the first seal ring interconnect structure, and/or the second seal ring interconnect structure. The semiconductor devices may be configured to modify a conductivity of the keep-out-zone interconnect structures, the first seal ring interconnect structure, and/or the second seal ring interconnect structure coupled thereto. Optionally, the method 1400 may include designating the first seal ring area and/or the second seal ring area to have diagonal edges at corners thereof. In some examples, the method 1400 may include forming one or more crack mitigation features at one or more of the corners of first seal ring area and/or the second seal ring area. The method 1400 may end at 1418.

The present disclosure therefore provides systems that include an interposer and methods for forming such systems that may have interconnection areas that are significantly larger in area relative to interposers produced using certain existing methods.

In accordance with an embodiment, an interposer is provided that includes an interconnection area that includes one or more frontside metal layers, one or more backside metal layers, and through silicon vias connecting the one or more frontside metal layers to the one or more backside metal layers in the interconnection area, wherein the interconnection area is larger than a shot size of a lithography system used for production thereof, a keep-out-zone area, wherein the keep-out-zone area surrounds a perimeter of the interconnection area, and a first seal ring area that includes a first seal ring interconnect structure, wherein the first seal ring area surrounds a perimeter of the keep-out-zone area. The interconnection area is segmented into two or more sub-regions that are each equal to or smaller than the shot size of the lithography system.

In accordance with another embodiment, a system is provided that includes two or more dies each including one or more functional components configured to perform a task, and an interposer functionally coupled with each of the two or more dies and configured to transmit signals received from each of the two or more dies to another of the two or more dies and/or to another electronic device. The interposer includes an interconnection area that includes one or more frontside metal layers, one or more backside metal layers, and through silicon vias connecting the one or more frontside metal layers to the one or more backside metal layers in the interconnection area, wherein the interconnection area is larger than a shot size of a lithography system used for production thereof, a keep-out-zone area, wherein the keep-out-zone area surrounds a perimeter of the interconnection area, a first seal ring area that includes a first seal ring interconnect structure, wherein the first seal ring area surrounds a perimeter of the keep-out-zone area, and one or more semiconductor devices that are functionally coupled with one or more keep-out-zone interconnect structures disposed in the keep-out-zone area and/or the first seal ring interconnect structure, wherein the one or more semiconductor devices are configured to modify a conductivity of the keep-out-zone interconnect structures and/or the first seal ring interconnect structure coupled thereto.

In accordance with yet another embodiment, a method is provided for forming an interposer. The method includes designating portions of an interposer to be produced on a wafer, wherein the portions of the interposer include an interconnection area, a keep-out-zone area, and a first seal ring area of the interposer, wherein the keep-out-zone area surrounds the interconnection area and the first seal ring area surrounds the keep-out-zone area, forming, with a lithography system, one or more frontside metal layers, one or more backside metal layers, and through silicon vias connecting the one or more frontside metal layers to the one or more backside metal layers in the interconnection area, wherein the interconnection area is larger than a shot size of the lithography system, wherein the interconnection area is segmented into two or more sub-regions that are each equal to or smaller than the shot size of the lithography system, wherein adjacent edges between the two or more sub-regions overlap, and forming a first seal ring interconnect structure in the first seal ring area.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An interposer, comprising:
an interconnection area that includes one or more frontside metal layers, one or more backside metal layers, and through silicon vias connecting the one or more frontside metal layers to the one or more backside metal layers in the interconnection area, wherein the interconnection area is larger than a shot size of a lithography system used for production thereof, wherein the interconnection area is segmented into two or more sub-regions that are each equal to or smaller than the shot size of the lithography system;
a keep-out-zone area, wherein the keep-out-zone area surrounds a perimeter of the interconnection area; and
a first seal ring area that includes a first seal ring interconnect structure, wherein the first seal ring area surrounds a perimeter of the keep-out-zone area.

2. The interposer of claim 1, further comprising a second seal ring area that includes a second seal ring interconnect structure, wherein the second seal ring area surrounds a perimeter of the first seal ring area.

3. The interposer of claim 2, further comprising one or more semiconductor devices that are functionally coupled with one or more keep-out-zone interconnect structures, the first seal ring interconnect structure, and/or the second seal ring interconnect structure, wherein the one or more semiconductor devices are configured to modify a conductivity of the keep-out-zone interconnect structures, the first seal ring interconnect structure, and/or the second seal ring interconnect structure coupled thereto.

4. The interposer of claim 3, wherein the one or more semiconductor devices include a CMOS transistor or an SiGe transistor.

5. The interposer of claim 2, further comprising one or more crack mitigation features at one or more corners of first seal ring area and/or the second seal ring area.

6. The interposer of claim 2, wherein the first seal ring area and/or the second seal ring area have diagonal edges at corners thereof.

7. A system, comprising:
two or more dies each including one or more functional components configured to perform a task; and
an interposer functionally coupled with each of the two or more dies and configured to transmit signals received from each of the two or more dies to another of the two or more dies and/or to another electronic device, wherein the interposer includes:
an interconnection area that includes one or more frontside metal layers, one or more backside metal layers, and through silicon vias connecting the one or more frontside metal layers to the one or more backside metal layers in the interconnection area, wherein the interconnection area is larger than a shot size of a lithography system used for production thereof;
a keep-out-zone area, wherein the keep-out-zone area surrounds a perimeter of the interconnection area;
a first seal ring area that includes a first seal ring interconnect structure, wherein the first seal ring area surrounds a perimeter of the keep-out-zone area; and
one or more semiconductor devices that are functionally coupled with one or more keep-out-zone interconnect structures and/or the first seal ring interconnect structure, wherein the one or more semiconductor devices are configured to modify a conductivity of the keep-out-zone interconnect structures and/or the first seal ring interconnect structure coupled thereto.

8. The system of claim 7, further comprising a second seal ring area that includes a second seal ring interconnect structure, wherein the second seal ring area surrounds a perimeter of the first seal ring area.

9. The system of claim 8, the first seal ring area and/or the second seal ring area have diagonal edges at corners thereof.

10. The system of claim 8, further comprising one or more crack mitigation features at one or more corners of first seal ring area and/or the second seal ring area.

11. The system of claim 7, wherein the one or more semiconductor devices include a CMOS transistor or an SiGe transistor.

12. The system of claim 7, further comprising a package substrate functionally coupled to the interposer and a circuit board functionally coupled to the package substrate, wherein the package substrate is configured to transmit signals received from the interposer to the circuit board, and the circuit board is configured to transmit the signals received from the package substrate to one or more other electronic devices functionally coupled to the circuit board.

13. A method, comprising:
designating portions of an interposer to be produced on a wafer, wherein the portions of the interposer include an interconnection area, a keep-out-zone area, and a first seal ring area of the interposer, wherein the keep-out-zone area surrounds the interconnection area and the first seal ring area surrounds the keep-out-zone area;
forming, with a lithography system, one or more frontside metal layers, one or more backside metal layers, and through silicon vias connecting the one or more frontside metal layers to the one or more backside metal layers in the interconnection area, wherein the interconnection area is larger than a shot size of the lithography system, wherein the interconnection area is segmented into at least a first sub-region and a second sub-region that are each equal to or smaller than the shot size of the lithography system by first exposing the first sub-region with the lithography system and then exposing a second sub-region with the lithography system, wherein adjacent edges between the first sub-region and the second subregion overlap; and
forming a first seal ring interconnect structure in the first seal ring area.

14. The method of claim 13, wherein designating the portions of the interposer on the wafer includes designating the first seal ring area to have diagonal edges at corners thereof.

15. The method of claim 13, further comprising forming one or more crack mitigation features at one or more corners of first seal ring area.

16. The method of claim 13, further comprising forming one or more semiconductor devices in the wafer that are functionally coupled with one or more keep-out-zone interconnect structures and/or the first seal ring interconnect structure, wherein the one or more semiconductor devices are configured to modify a conductivity of the keep-out-zone interconnect structures and/or the first seal ring interconnect structure coupled thereto.

17. The method of claim 13, further comprising:
designating a second seal ring area that surrounds the first seal ring area; and
forming a second seal ring interconnect structure in the second seal ring area.

18. The method of claim 17 further comprising forming one or more semiconductor devices in the wafer that are functionally coupled with the second seal ring interconnect structure, wherein the one or more semiconductor devices are configured to modify a conductivity of the second seal ring interconnect structure coupled thereto.

19. The method of claim 17, wherein designating the portions of the interposer on the wafer includes designating the second seal ring area to have diagonal edges at corners thereof.

20. The method of claim 17, further comprising forming one or more crack mitigation features at one or more of corners of the second seal ring area.
